(19) United States
(12) Patent Application Publication
(10) Pub. No.: US 2005/0094383 A1
(43) Pub. Date: May 5, 2005

(54) Substrate for use in forming electronic package

(75) Inventor: Sheng Tsung Liu, Kaohsiung City (TW)

Correspondence Address: LOWE HAUPTMAN GILMAN AND BERNER, LLP, 1700 DIAGONAL ROAD, SUITE 300 /310, ALEXANDRIA, VA, 22314, US

(73) Assignee: ADVANCED SEMICONDUCTOR ENGINEERING, INC., Kaohsiung (TW)

(21) Appl. No.: 10/980,319

(22) Filed: Nov. 4, 2004

(30) Foreign Application Priority Data
Nov. 5, 2003 (TW) 092130996

(51) Int. Cl. H05K 7/06

(52) U.S. Cl. 361/780; 361/782; 361/783

(57) ABSTRACT

Disclosed is a substrate for use in forming an electronic package. The substrate includes a dielectric layer having first and second patterned metal films which have different area, first and second contact pads and first and second conductive traces formed thereon. The first and second contact pads are adapted for connecting to a surface-mountable device. Each of the contact pads has an area smaller than the area of the patterned metal film. The first contact pad is separated from the first patterned metal film by a first predetermined distance and the second contact pad is separated from the second patterned metal film by a second predetermined distance. The first contact pad is connected to the first patterned metal film by the first conductive trace, and the second contact pad is connected to the second patterned metal film by the second conductive trace.

This application claims the priority benefit of Taiwan Patent Application Serial Number 092130996, filed Nov. 5, 2003, the full disclosure of which is incorporated herein by reference.

### BACKGROUND OF THE INVENTION

1. Field of the Invention

The present invention relates to a substrate for use in forming electronic package.

2. Description of the Related Art

An electronic package generally comprises more than one active component disposed on a circuit substrate. The active component is a chip generally cut from a wafer, which is made of silicon, germanium arsenide or gallium arsenide. The package having only one component is referred to as Single-Chip Module (SCM), whereas the package having a plurality of components is referred to as Multi-Chip Module (MCM). Generally speaking, a chip is encapsulated in epoxy for protection.

As the operating speed increases in electronic packages, the noises generated from direct current trace and ground trace will gradually become a non-neglected problem. Therefore, it is very common to use passive component such as capacitor (referred to as decoupling capacitor) for reducing power supply noises generated from the variation of potential difference between power voltage and ground voltage. The decoupling capacitor is disposed as closely as possible to an active component so as to enhance its effect. The passive components are typically integrated onto a substrate.

Generally speaking, a plurality of passive components are collectively connected to a power trace or a ground trace on a substrate. Therefore, the substrate is provided with a plurality of relatively larger areas of patterned metal films serving as power traces or ground traces and a plurality of contact pads, which are defined by the solder masks covering the patterned metal films. The passive components are generally surface-mountable devices of which both end contacts are separately secured to the contact pads on the substrate by means of the surface mount technology (SMT). The contact pads are defined respectively in the power and ground patterned metal films. On a conventional substrate, the contact pad is defined by the solder masks covering the patterned metal films and the patterned metal films adapted for providing power or ground individually have different areas. For this reason, the contact pads defined by the different patterned metal films that underlie the solder masks actually have different areas. During securing both end contacts of the passive components separately to the contact pads on the substrate in a reflow step of SMT, the heat absorbed by the contact pads will be different because the patterned metal films containing the contact pads have different areas. Accordingly, the solders disposed on the different contact pads for securing both ends of the passive component often melt unequally in a reflow step. Hence, it is likely to have bad soldering on both ends of the passive component and a shift or tomb stone effect (with one end of a component secured and the other end raised up) of the passive component.

Therefore, it is necessary to develop a substrate for use in forming electronic package in order to overcome or at least to solve the problems in the prior art.

### SUMMARY OF THE INVENTION

It is a primary object of the invention to provide a substrate for use in forming electronic package characterized in that a plurality of contact pads having substantially identical areas are disposed on the substrate for respective connection to the surface-mountable devices by soldering.

According to an embodiment of the present invention, a substrate includes a dielectric layer having two patterned metal films that have different areas, first and second contact pads, and first and second conductive traces formed thereon. The first and second contact pads are adapted for connection with a surface-mountable device. Each of the contact pads has an area smaller than the area of the corresponding patterned metal film. The first contact pad is separated from the patterned metal film with a larger area by a predetermined distance and the second contact pad is separated from the patterned metal film with a smaller area by a predetermined distance. Preferably, the predetermined distance is greater than 10 mils. The first conductive trace connects the first contact pad and the patterned metal film with a larger area and the second conductive trace connects the second contact pad and the patterned metal film with a smaller area. Preferably, the widths of the conductive traces are smaller than one half of those of the contact pads and are greater than 5 mils.

The substrate according to the present invention may have contact pads with substantially identical areas, and therefore during securing surface-mountable devices to the substrate in a reflow step every contact pad can equally absorb heat so that the solder will equally melt. Accordingly, it can solve the problem in the prior art that the solders on different contact pads melt unequally.

### BRIEF DESCRIPTION OF THE DRAWINGS

Other objects, advantages, and novel features of the invention will become more apparent from the following detailed description when taken in conjunction with the accompanying drawing.

FIG. 1 is a schematic top view showing a partial electronic package according to an embodiment of the present invention.

FIG. 2 is a cross-section view along the Line 2-2 of FIG. 1.

### DESCRIPTION OF THE PREFERRED EMBODIMENT

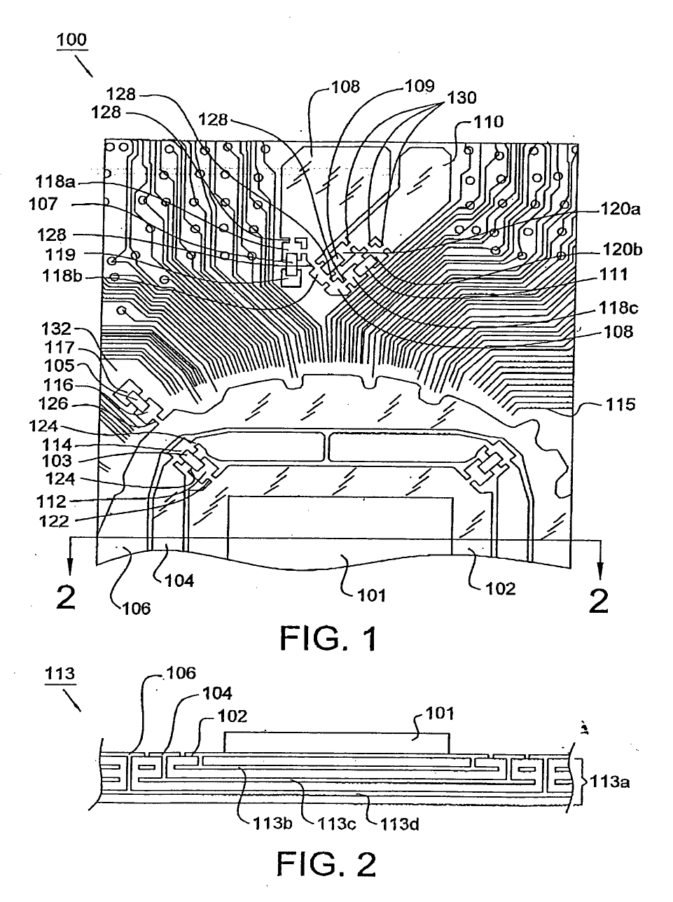

FIG. 1 and FIG. 2 are a top view showing a partial electronic package 100 and a cross-section view according to an embodiment of the invention. The electronic package 100 generally comprises more than one active component such as a semiconductor chip 101 and surface-mountable devices such as passive components 103, 105, 107, 109 and 111 disposed on a substrate 113. The substrate 113 comprises a dielectric layer 113a with a signal trace 115 formed thereon, patterned metal films 102, 104, 106, 108 and 110, contact pads 112, 114, 116, 117, 118a, 118b, 118c, 119, 120a and 120b, and conductive traces 122, 124, 126, 128 and 130. It should be noted that the areas of the contact pads 112, 114, 116, 117, 118a, 118b, 118c, 119, 120a and 120b are all smaller than those of the patterned metal films 102, 104, 106, 108 and 110.

The patterned metal film 102 is formed on the substrate 113 as a die pad for connecting to a ground reference potential, for example, a ground plane 113b (as shown in FIG. 2) disposed in the substrate 113, so as to provide a ground potential. The patterned metal film 104 surrounds the patterned metal film 102 and is adapted for connecting to a power reference potential, for example, a power plane 113c disposed in the substrate 113, so as to provide a power potential. The patterned metal film 106 surrounds the outside of the patterned metal film 104 and is adapted for connecting to a power reference potential, for example, a power plane 113d disposed in the substrate 113, so as to provide a further power potential. Furthermore, the periphery of substrate 113 is further provided with patterned metal films 108 and 110, which are connected to a ground reference potential. The contact pads 117 and 119 are not connected to the patterned metal films 102, 104, 106, 108 and 110 and the contact pads 112, 114, 116, 118a, 118b, 118c, 120a and 120b are separated from the adjacent patterned metal films 102, 104, 106, 108 or 110 by a predetermined distance. Preferably, the predetermined distance is greater than 10 mils.

The contact pad 112 is connected to the adjacent patterned metal film 102 by a conductive trace 122 so that the contact pad 112 can provide the ground potential. The contact pad 114 is connected to the adjacent patterned metal film 104 by two conductive traces 124 so that the contact pad 114 can provide the power potential provided by the patterned metal film 104. The contact pad 116 is connected to the adjacent patterned metal film 106 by a conductive trace 126 so that the contact pad 116 can provide the power potential provided by the patterned metal film 106. The contact pads 118a, 118b and 118c are connected to the patterned metal film 108 by a plurality of conductive traces 128. The contact pads 120a and 120b are also connected to the patterned metal film 110 by a plurality of conductive traces 130. It should be noted that the width of the conductive trace is smaller than one half of that of the contact pad, so that the patterned metal conductive layer connected to the contact pad does not influence the heat absorption speed of the contact pad. Furthermore, in order to make the resistance of conductive trace not too large to influence the efficiency of the electronic package, the width of the conductive trace should be greater than 5 mils.

The semiconductor chip 101 is disposed on the patterned metal film (the die pad) 102 and is electrically connected to the patterned metal film 102 and the signal trace 115. According to the surface-mountable device of the present invention, preferably it should be a passive component. It should be understood that the passive component may comprise capacitors, resistors and inductor-made filters, thereby suppresses power supply noises and raises the operation speed of a chip. In this embodiment of the present invention, both end contacts of a passive component 103 are secured separately to the contact pads 112 and 114 with surface mount technology (e.g. a reflow step). Both end contacts of a passive component 105 are secured separately to the contact pads 116 and 117 with surface mount technology (SMT). Both end contacts of a passive component 107 are secured separately to the contact pads 118a and 119 with surface mount technology (SMT). Both end contacts of a passive component 109 are secured separately to the contact pads 118b and 120a with surface mount technology. Both end contacts of a passive component 111 are secured separately to the contact pads 118c and 120b with surface mount technology.

Conventional process for making a substrate comprises: (A) laminating a conductive metal layer (e.g. a copper foil with roughened surface) with conventional methods (e.g. thermocompression bonding) between both sides of a dielectric layer (e.g. BT (bismaleimide-triazine) resin, FR-4 fiberglass reinforced epoxy resin). (B) forming vias or through-holes on the substrate with any well-known methods (e.g. mechanical drilling, laser drilling) and applying a layer of conductive metal (e.g. copper) to the vias or the through-holes with well-known methods (e.g. electroless plating). (C) applying a photoresist layer to a conductive metal layer laminated on the dielectric layer with well-known methods and materials for transferring the desired pattern and then developing. As everyone knows, a photomask is used to pattern the photoresist layer on a specific area. After developing, the photoresist on the specific area will be removed so that the predetermined part of the conductive metal layer is exposed on the photoresist layer. (D) etching the exposed part of the conductive metal layer for forming the desired conductive trace or metal conductive layer, e.g. metal films 102, 104, 106, 108 and 110, contact pads 112, 114, 116, 117, 118a, 118b, 118c, 119, 120a and 120b, and conductive traces 122, 124, 126, 128 and 130. (E) covering the substrate with a photoimagable solder mask to transfer the desired pattern and then develop to expose the conductive areas connecting out of the contact pads 112, 114, 116, 117, 118a, 118b, 118c, 119, 120a and 120b. It is to be noted that, referring to FIG. 1, the solder mask 132 covers the entire upper surface of the patterned metal films 102, 104, 106, 108 and 110, and the periphery of the contact pads 112, 114, 116, 117, 118a, 118b, 118c, 119, 120a and 120b so that the middle parts of the contact pads 112, 114, 116, 117, 118a, 118b, 118c, 119, 120a and 120b are exposed for external connections. (F) electroplating a material (e.g. gold or palladium) having a good bond to a conventional bonding wire to the conductive areas that solder masks do not cover.

Generally speaking, in mass production it is preferred to integrate a plurality of substrates into a substrate strip and dispose alignment holes on a substrate strip so as to automate a package process.

In well-known art, a contact pad is defined by the solder masks covering the patterned metal films. The patterned metal films adapted for providing power or ground individually have different areas, so that the patterned metal films which underlie the solder masks of the contact pads defined by the different metal films actually have different areas. For this reason, the solders disposed on the different contact pads for securing both ends of the passive component often melt unequally in a reflow step. Hence it is likely to have bad soldering on both ends of the passive component and a shift or tomb stone effect (with one end of a component secured and the other end raised up) of the passive component. On the contrary, according to the substrate of the present invention, the contact pads for external connections have substantially identical areas, are spaced away from the adjacent patterned metal films with an adequate distance and are connected separately to the patterned metal film by a conductive trace with an adequate width. Therefore, during securing surface-mountable devices to the substrate by the solders disposed on the contact pads in a reflow step of SMT, the contact pads have substantially identical heat absorption speed so that the solders thereon will be heated uniformly and then melt equally. Accordingly, it can solve the problem in the prior art that the solders on the contact pads melt unequally since the contact pads have different real areas.

Although the invention has been explained in relation to its preferred embodiment, it is not used to limit the invention. It is to be understood that many other possible modifications and variations can be made by those skilled in the art without departing from the spirit and scope of the invention as hereinafter claimed.

1. A substrate for use in forming electronic package, comprising:
a dielectric layer;
a first patterned metal film formed on the dielectric layer;
a first and second contact pads adapted for connecting to a surface-mountable device, each of the contact pads having an area smaller than that of the first patterned metal film, wherein the first contact pad is separated from the first patterned metal film by a first predetermined distance; and
a first conductive trace connecting the first contact pad to the first patterned metal film.

2. The substrate for use in forming electronic package as claimed in claim 1, further comprising:
a second patterned metal film which has an area smaller than that of the first patterned metal film, wherein the second contact pad is separated from the second patterned metal film by a second predetermined distance; and
a second conductive trace connecting the second contact pad to the second patterned metal film.

3. The substrate for use in forming electronic package as claimed in claim 2, wherein the width of the second conductive trace is smaller than one half of that of the second contact pad.

4. The substrate for use in forming electronic package as claimed in claim 2, wherein the width of the second conductive trace is greater than 5 mils.

5. The substrate for use in forming electronic package as claimed in claim 2, wherein the distance between the second contact pad and the second patterned metal film is greater than 10 mils.

6. The substrate for use in forming electronic package as claimed in claim 2, further comprising:
a ground plane disposed in the substrate, wherein the second patterned metal film is electrically connected to the ground plane.

7. The substrate for use in forming electronic package as claimed in claim 2, further comprising:
a power plane disposed in the substrate, wherein the second patterned metal film is electrically connected to the power plane.

8. The substrate for use in forming electronic package as claimed in claim 1, wherein the width of the first conductive trace is smaller than one half of that of the first contact pad.

9. The substrate for use in forming electronic package as claimed in claim 1, wherein the width of the first conductive trace is greater than 5 mils.

10. The substrate for use in forming electronic package as claimed in claim 1, wherein the distance between the first contact pad and the first patterned metal film is greater than 10 mils.

11. The substrate for use in forming electronic package as claimed in claim 1, further comprising:
a ground plane disposed in the substrate, wherein the first patterned metal film is electrically connected to the ground plane.

12. The substrate for use in forming electronic package as claimed in claim 1, further comprising:
a power plane disposed in the substrate, wherein the first patterned metal film is electrically connected to the power plane.

13. An electronic package, comprising:
a substrate comprising a dielectric layer, a first patterned metal film formed on the dielectric layer, a first contact pad, a second contact pad, a plurality of signal traces, and at least a first conductive trace connecting the first contact pad to the first patterned metal film, each of the contact pads having an area smaller than that of the first metal film, wherein the first contact pad is separated from the first patterned metal film by a first predetermined distance;
an active component disposed on the substrate and electrically connected to the first patterned metal film and the signal traces; and
a first passive component disposed across on the first and second contact pads.

14. The electronic package as claimed in claim 13, wherein the first patterned metal film disposed in the periphery of the substrate.

15. The electronic package as claimed in claim 13, wherein the distance between the first contact pad and the first patterned metal film is greater than 10 mils.

16. The electronic package as claimed in claim 13, further comprising:
a first power plane disposed in the substrate, wherein the first patterned metal film is electrically connected to the first power plane.

17. The electronic package as claimed in claim 13, further comprising:
a second patterned metal film which has an area smaller than that of the first patterned metal film, wherein the second contact pad is separated from the second patterned metal film by a second predetermined distance; and
a second conductive trace connecting the second contact pad to the second patterned metal film.

18. The electronic package as claimed in claim 17, wherein the distance between the second contact pad and the second patterned metal film is greater than 10 mils.

19. The electronic package as claimed in claim 13, wherein the substrate further comprises:
a die pad formed on the substrate, a third patterned metal film surrounding the die pad, a third contact pad, a fourth contact pad, at least a third conductive trace connecting the third contact pad to the die pad, and at least a fourth conductive trace connecting the fourth contact pad to the third patterned metal film, the areas of the contact pads being smaller than area of the die pad and areas of the patterned metal films, the electronic package further comprising a second passive component disposed across on the third and fourth contact pads.

20. The electronic package as claimed in claim 19, wherein the first patterned metal film surrounds the third patterned metal film.

21. The electronic package as claimed in claim 19, wherein the distances from the third and fourth contact pads to the die pad and the third patterned metal film are greater than 10 mils.

22. The electronic package as claimed in claim 19, further comprising:
a ground plane disposed in the substrate, wherein the die pad is electrically connected to the ground plane.

23. The electronic package as claimed in claim 19, further comprising:
a second power plane disposed in the substrate, wherein the third patterned metal film is electrically connected to the second power plane.

24. The electronic package as claimed in claim 13, wherein the widths of the conductive traces are smaller than one half of those of the contact pads connecting with the conductive traces.

25. The electronic package as claimed in claim 13, wherein the widths of the conductive traces are greater than 5 mils.

26. An electronic package, comprising:
a substrate comprising a dielectric layer, a die pad formed thereon, a patterned metal film surrounding the die pad, a first contact pad, a second contact pad, a plurality of signal traces, at least a first conductive trace connecting the first contact pad to the die pad, and at least a second conductive trace connecting the second contact pad to the patterned metal film, wherein the area of each of the contact pads is smaller than that of the die pad and that of the patterned metal film;
an active component disposed on the die pad and electrically connected to the patterned metal film and the signal traces; and
a passive component disposed across on the first and second contact pads.

27. The electronic package as claimed in claim 26, wherein the widths of the conductive traces are smaller than one half of those of the contact pads.

28. The electronic package as claimed in claim 26, wherein the widths of the conductive traces are greater than 5 mils.

29. The electronic package as claimed in claim 26, wherein the distances from the contact pads to the die pad and to the patterned metal film are greater than 10 mils.

30. The electronic package as claimed in claim 26, further comprising:
a ground plane disposed in the substrate, wherein the die pad is electrically connected to the ground plane.

31. The electronic package as claimed in claim 26, further comprising:
a power plane disposed in the substrate, wherein the patterned metal film is electrically connected to the power plane.
